(19) United States
(12) Patent Application Publication
(10) Pub. No.: US 2025/0016981 A1
(43) Pub. Date: Jan. 9, 2025

(54) INTEGRATED CIRCUIT MEMORY DEVICES HAVING HIGHLY INTEGRATED MEMORY CELLS THEREIN WITH ENHANCED LANDING PAD STRUCTURES

(71) Applicant: Samsung Electronics Co., Ltd., Suwon-si (KR)

(72) Inventors: Yoonhwan Choi, Suwon-si (KR); Masayuki Terai, Suwon-si (KR)

(21) Appl. No.: 18/653,157

(22) Filed: May 2, 2024

(30) Foreign Application Priority Data
Jul. 5, 2023 (KR) 10-2023-0087019

(51) Int. Cl. H10B 12/00

(52) U.S. Cl. CPC H10B 12/315; H10B 12/05

(57) ABSTRACT

An integrated circuit memory device includes a substrate having a bit line thereon, and a channel structure extending on the bit line. The channel structure includes a horizontal portion on the bit line and a vertical channel portion extending upwardly from one end of the horizontal portion. A word line is provided, which extends opposite the horizontal portion and crosses the bit line to extend in a second horizontal direction, which intersects the first horizontal direction. A landing pad structure is provided, and is electrically connected to the vertical channel portion. The landing pad structure includes a first contact portion in contact with an upper surface of the vertical channel portion and a second contact portion protruding downwardly from a lower surface of the first contact portion.

### REFERENCE TO PRIORITY APPLICATION

This application claims priority to Korean Patent Application No. 10-2023-0087019, filed Jul. 5, 2023, the disclosure of which is hereby incorporated herein by reference.

### BACKGROUND

The present inventive concept relates to semiconductor devices having landing pad structures therein.

With an increase in demand for high performance, high speed, and/or multi-functionalization of semiconductor devices, the degree of integration of semiconductor devices has increased. When manufacturing semiconductor devices having a fine pattern corresponding to the tendency for high integration of semiconductor devices, there is often a need for implementation of patterns having a fine width or a fine separation distance.

### SUMMARY

An aspect of the present inventive concept is to provide semiconductor devices having a landing pad structure that includes a first contact portion and a second contact portion in contact with a channel structure.

According to an aspect of the present disclosure, a semiconductor device may include: a bit line extending in a first horizontal direction; a channel structure disposed on the bit line, wherein the channel structure includes a horizontal portion on the bit line and a vertical channel portion extending upwardly from one end of the horizontal portion; a word line disposed on the horizontal portion and crossing the bit line to extend in a second horizontal direction, intersecting the first horizontal direction; and a landing pad structure disposed on the vertical channel portion and electrically connected to the channel structure. The landing pad structure may include a first contact portion in contact with an upper surface of the vertical channel portion and a second contact portion protruding downwardly from a lower surface of the first contact portion.

According to another aspect of the present disclosure, a semiconductor device may include: a bit line extending in a first horizontal direction; a mold structure disposed on the bit line and extending in a second horizontal direction, intersecting the first horizontal direction, wherein the mold structure includes a mold layer and a liner on a side surface of the mold layer; a channel structure disposed on the bit line, wherein the channel structure includes a horizontal portion on the bit line and a vertical channel portion extending upwardly from one end of the horizontal portion and disposed on a side surface of the liner; a word line disposed on the horizontal portion and crossing the bit line to extend in the second horizontal direction; and a landing pad structure disposed on the vertical channel portion and electrically connected to the channel structure. An upper surface of the vertical channel portion may be disposed on a higher level than an upper surface of the liner. The landing pad structure may include a first contact portion in contact with the upper surface of the vertical channel portion, and a second contact portion in contact with a side surface of an upper region of the vertical channel portion and the upper surface of the liner.

According to a further aspect of the present disclosure, a semiconductor device may include: a lower substructure including a circuit element; a bit line disposed on the lower structure and extending in a first horizontal direction; a mold structure disposed on the bit line and extending in a second horizontal direction, intersecting the first horizontal direction, wherein the mold structure includes a mold layer and a liner on a side surface of the mold layer; a channel structure disposed on the bit line, wherein the channel structure includes a horizontal portion on the bit line and a vertical channel portion extending upwardly from one end of the horizontal portion and disposed on a side surface of the liner; a word line disposed on the horizontal portion and crossing the bit line to extend in the second horizontal direction; an upper insulating structure spaced apart from the mold structure in the second horizontal direction and configured to cover the word line and the bit line; an upper capping layer configured to cover the mold structure and the upper insulating structure; and a landing pad structure disposed on the vertical channel portion, penetrating through the upper capping layer, and electrically connected to the channel structure; and an information storage structure disposed on the landing pad structure. The landing pad structure may include a pad portion on the upper capping layer, a first contact portion in contact with an upper surface of the vertical channel portion, a second contact portion in contact with a side surface of the vertical channel portion and an upper surface of the liner, and a connection portion between the pad portion and the first contact portion.

According to some example embodiments of the technical concept of the present disclosure, a landing pad structure may include a first contact portion and a second contact portion protruding downwardly from a lower surface of the first contact portion. Since the first contact portion and the second contact portion are in contact with a channel structure, a contact area between the landing pad structure and the channel structure may be advantageously increased and a contact resistance may be reduced.

According to further example embodiments of the technical concept, an integrated circuit memory device is provided, which includes a substrate having a bit line thereon, and a channel structure. The channel structure includes a horizontal portion on the bit line, and a vertical channel portion having a first end electrically connected to an end of the horizontal portion, with the vertical channel portion extending upwardly relative to an underlying portion of the substrate. A word line is provided, which extends on the horizontal portion of the channel structure and opposite the vertical channel portion, such that a portion of the word line extending opposite the vertical channel portion operates as a gate electrode of a first memory cell access transistor. A landing pad structure is provided, which extends on and is electrically connected to a second end of the vertical channel portion. In particular, the landing pad structure includes: (i) a first contact portion that electrically contacts the second end of the vertical channel portion, and (ii) a second contact portion that electrically contacts a portion of a vertical sidewall of the vertical channel portion that extends between the second contact portion and the word line. In some cases, the vertical channel portion of the channel structure may have a generally L-shaped cross-section. A storage electrode of a DRAM capacitor may also be provided, which contacts an upper surface of the landing pad.

In some of these embodiments, an electrically insulating mold layer may be provided on the bit line, and the vertical channel portion of the channel structure may extend along a first sidewall of the mold layer. Advantageously, to reduce total contact resistance (to the vertical channel portion), the second contact portion may extend between the vertical channel portion and the mold layer, to thereby increase contact surface area. In some embodiments, an electrically insulating liner may be provided, which extends between the vertical channel portion and the mold layer. The mold layer may also include a lower mold layer and an upper mold layer on the lower mold layer. In some embodiments, the liner, the lower mold layer and the upper mold layer consist of different electrically insulating materials.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor device according to an example embodiment;

FIG. 1B is a vertical cross-sectional view taken along line I-I′ of the semiconductor device illustrated in FIG. 1A;

FIG. 1C is a vertical cross-sectional view taken along line II-II′ of the semiconductor device in FIG. 1A;

FIG. 2 is a partially enlarged view of the semiconductor device illustrated in FIG. 1B;

FIGS. 3 to 7 are vertical cross-sectional views of a semiconductor device according to an example embodiment;

FIG. 8 is a vertical cross-sectional view of a semiconductor device according to an example embodiment;

FIG. 9 is a vertical cross-sectional view of a semiconductor device according to an example embodiment;

FIG. 10 is a partially enlarged view of the semiconductor device illustrated in FIG. 9; and

FIGS. 11A to 21 are plan views and vertical cross-sectional view illustrated according to a process order to explain a method of manufacturing a semiconductor device according to an example embodiment.

### DETAILED DESCRIPTION

Hereinafter, example embodiments of the present inventive concept will be described with reference to the accompanying drawings.

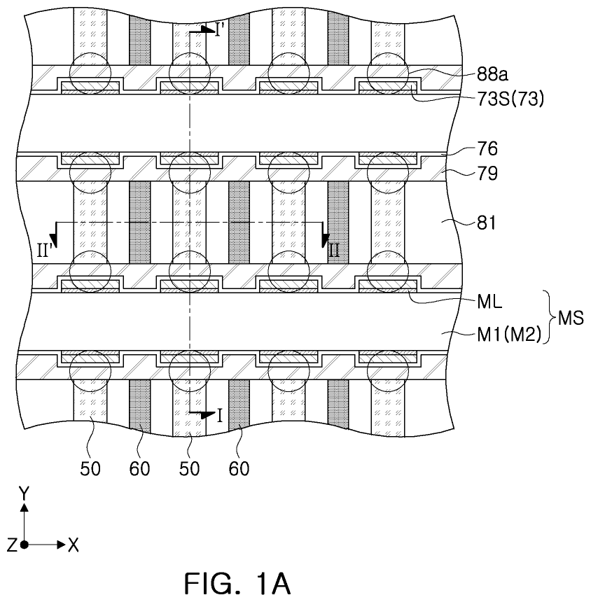

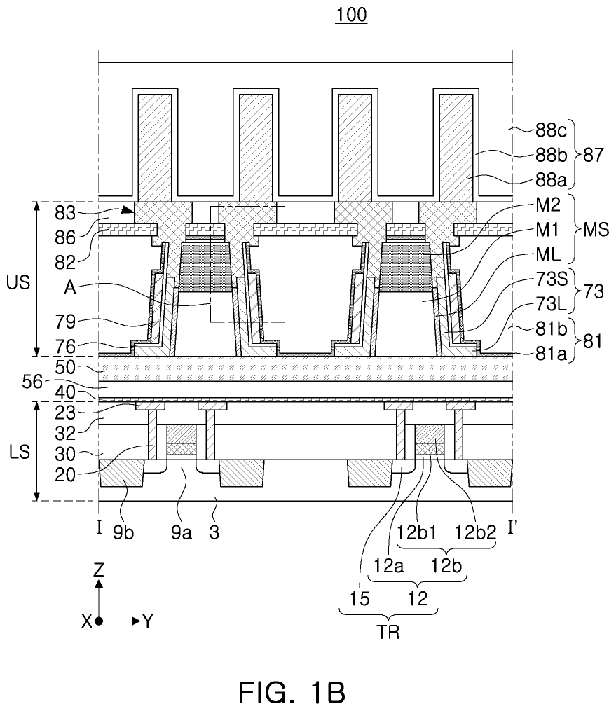

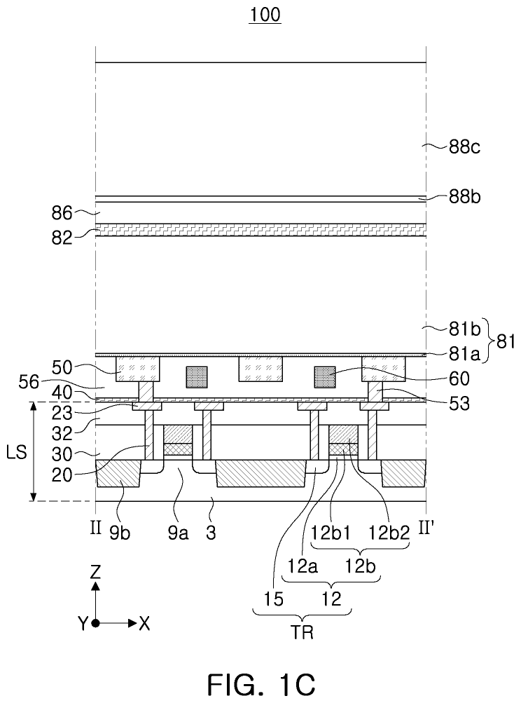

FIG. 1A is a plan view of a semiconductor device according to an example embodiment; FIG. 1B is a vertical cross-sectional view taken along line I-I′ of the semiconductor device illustrated in FIG. 1A; and FIG. 1C is a vertical cross-sectional view taken along line II-II′ of the semiconductor device in FIG. 1A. Referring now to FIGS. 1A to 1C, a semiconductor device 100 according to an example embodiment of the present disclosure may include a lower structure LS, a bit line 50, an upper structure US, and an information storage structure 87. The lower structure LS may include a substrate 3, a circuit element TR, a peripheral plug 20, a peripheral wiring 23, a first peripheral insulating layer 30, and a second peripheral insulating layer 32.

The substrate 3 may include a semiconductor material, for example, a Group IV semiconductor, a Group Ill-V compound semiconductor, or a Group II-VI compound semiconductor. For example, the Group IV semiconductor may include silicon, germanium, or silicon-germanium. The substrate 3 may be a silicon substrate, a silicon on insulator (SOI) substrate, a germanium substrate, a germanium on insulator (GOI) substrate, a silicon-germanium substrate, or a substrate including an epitaxial layer.

The circuit element TR may include a word line driver, a sense amplifier, row and column decoders, and control circuits. The circuit element TR may include a peripheral transistor. For example, the peripheral transistor may include a gate structure 12 disposed on a peripheral active region 9a limited by a device isolation region 9b in the substrate 3 and peripheral source/drain regions 15 disposed within the peripheral active region 9a on both sides of the gate structure 12.

The gate structure 12 may include a peripheral gate electrode 12b and a peripheral gate dielectric layer 12a between the peripheral gate electrode 12b and the peripheral active region 9a. The peripheral gate electrode 12b may include at least two conductive layers, for example, a first conductive layer 12b1 and a second conductive layer 12b2 on the first conductive layer 12b1.

A peripheral plug 20 may be connected to the peripheral source/drain region 15 and may extend vertically, and a peripheral wiring 23 may be disposed on the peripheral plug 20. The peripheral wiring 23 may be electrically connected to the circuit element TR through the peripheral plug 20. A first peripheral insulating layer 30 may surround side surfaces of the peripheral gate electrode 12b and the peripheral plug 20. A second peripheral insulating layer 32 may be disposed on the first peripheral insulating layer 30 and may surround the peripheral plug 20 and the peripheral wiring 23. An upper surface of the second peripheral insulating layer 32 may be coplanar with an upper surface of the peripheral wiring 23.

In an example embodiment, the peripheral plug 20 and the peripheral wiring 23 may include a metal layer and a barrier layer configured to cover a side surface and a bottom surface of the metal layer. The barrier layer may include at least one of TiN, TaN, WN, TiSiN, TaSiN, and RuTiN, and the metal layer may include a metal material such as W or Mo. The first peripheral insulating layer 30 and the second peripheral insulating layer 32 may contain silicon oxide, silicon nitride, silicon oxynitride, a low dielectric, or combinations thereof.

The semiconductor device 100 may further include an etching stop layer 40 disposed on the lower structure LS. The etching stop layer 40 may cover the peripheral wiring 23 and the second peripheral insulating layer 32. The etching stop layer 40 may include SiBN, SiCN, SiN, or combinations thereof.

The bit line 50 may be disposed on the lower structure LS. The bit lines 50 may extend in a Y-direction and may be spaced apart from each other in an X-direction. The semiconductor device 100 may further include a bit line plug 53 disposed below the bit line 50, and a bit line insulating layer 56 surrounding the bit line 50 and the bit line plug 53. The bit line 50 may be electrically connected to the lower structure LS through the bit line plug 53.

The bit line 50 may include a metal layer and a barrier layer configured to cover a side surface and a bottom surface of the metal layer. The barrier layer may include at least one of TiN, TaN, WN, TiSiN, TaSiN, and RuTiN, and the metal layer may include a metal material such as W or Mo. The bit line plug 53 may include the same material as the peripheral plug 20 and the peripheral wiring 23. The bit line insulating layer 56 may include silicon oxide, silicon nitride, silicon oxynitride, a low dielectric material, or combinations thereof.

The semiconductor device 100 may further include shield patterns 60 extending in the Y-direction and spaced apart from each other in the X-direction. The shield patterns 60 may be alternately disposed with the bit lines 50 in the X-direction. A lower surface of the shield pattern 60 may be disposed on a lower level than that of a lower surface of the bit line 50, and an upper surface of the shield pattern 60 may be disposed on a lower level than the upper surface of the bit line 50. The shield patterns 60 may reduce capacitance between the bit lines 50.

The shield pattern 60 may include doped polysilicon, metal, conductive metal nitride, a metal-semiconductor compound, a metal compound, conductive metal oxide, graphene, a carbon nanotube, or combinations.

The upper structure US may be disposed on the bit line 50. The upper structure US may include a mold structure MS, a channel structure 73, a word line 79, an upper insulation structure 81, an upper capping layer 82, and a landing pad structure 83.

The mold structure MS may be disposed on the bit line 50. In a plan view, the mold structures MS may extend in the X-direction and may be spaced apart from each other in the Y-direction. The mold structure MS may include a lower mold layer M1, an upper mold layer M2, and a liner ML. The upper mold layer M2 may be disposed on the lower mold layer M1, and the lower mold layer M1 and the upper mold layer M2 may extend in the X-direction. The liner ML may cover a portion of a side surface of the upper mold layer M2 and a side surface of the lower mold layer M1. In a cross-sectional view, an upper surface of the liner ML may be disposed on a higher level than an upper surface of the lower mold layer M1, and may be disposed on a lower level than an upper surface of the upper mold layer M2. In a plan view, the liners ML may be spaced apart from each other in the X-direction and the Y-direction.

The lower mold layer M1 and the upper mold layer M2 may include silicon oxide, silicon nitride, silicon oxynitride, or a combination thereof. In an example embodiment, the lower mold layer M1 and the upper mold layer M2 may include different materials. For example, the lower mold layer M1 may include silicon oxide, and the upper mold layer M2 may include silicon nitride. The liner ML may include silicon oxide, silicon oxynitride, hafnium oxide, or combinations thereof.

The channel structure 73 may be disposed on the bit line 50. The channel structure 73 may include a horizontal portion 73L that is in contact with and is electrically connected to the bit line 50, and a vertical channel portion 73S extending upwardly from one end of the horizontal portion 73L in the Y-direction. A lower surface of the horizontal portion 73L may be in contact with the bit line 50, and the horizontal portion 73L may be electrically connected to the bit line 50. In an example embodiment, the vertical channel portion 73S may extend in a direction oblique to a vertical direction (Z-direction), but the present disclosure is not limited thereto. When viewed in a plan view, the channel structures 73 may be disposed on the side surfaces of the liners ML. The liner ML may be disposed between the channel structure 73 and the mold structure MS, and the channel structure 73 may be spaced apart from the mold structure MS. The channel structures 73 may be spaced apart from each other in the X-direction and the Y-direction. In an example embodiment, a horizontal width of each channel structure 73 in the X-direction may be the same as the horizontal width of each liner ML in the X-direction.

Although FIG. 1B illustrates that the channel structures 73 are spaced apart from each other, the present disclosure is not limited thereto. In some example embodiments, the horizontal portions 73L of the channel structures 73 disposed adjacently to each other and facing each other in the Y-direction may extend in the horizontal direction and may be integrally formed.

The channel structure 73 may be formed of a semiconductor material such as silicon. The channel structure 73 may be formed of single crystalline silicon or polysilicon. However, the channel structure 73 is not limited to semiconductor materials such as silicon, but may be formed of other semiconductor materials that may be used as a channel region of a transistor. For example, the channel structure 73 may include an oxide semiconductor layer or a two-dimensional material layer that can be used as a channel region of a transistor.

The oxide semiconductor layer may be indium gallium zinc oxide (IGZO). However, example embodiments are not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (ZnO), indium zinc oxide (ZnO), indium gallium zinc oxide (InGaZnO)), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

IWO (Indium Tungsten Oxide), ITGO (Indium Tin Galium Oxide), Indium Aluminum Zinc Oxide (IGO), Indium Gallium Oxide (IGO), Indium Tin Zinc Oxide (ITZO), ZTO (Zinium Oxide), Tinium Zinium Oxide (IGSO), Tinium Oxide (IGO), Indium Zinium Oxide (IZO), IGSO), Tinium Oxide (IZO), Ixide (IZO), Ixide (IZO), Ixide (I), indium gallium zinc oxide (InGaZnO), zirconium indium zinc oxide (ZrInZnO), hafnium indium zinc oxide (HfInZnO), tin indium zinc oxide (SnInZnO), aluminum indium zinc oxide (AlSnInZnO), silicon indium zinc oxide (SiZnZnO), tin (AlZnO), tin (ZnO), tin oxide (ZnO), tin oxide (ZnO), tin (AlZnO), tin oxide, tin oxide) tin (ZnO), tin (ZnO), tin oxide (ZnO) tin oxide (ZnO.

The two-dimensional material layer may include at least one of a transition metal dichalcogenide material layer, a black phosphorous material layer, and a hexagonal Boron-Nitride (hBN) material layer, which may have semiconductor characteristics. For example, the two-dimensional material layer may include at least one of BiOSe, CrI, WSe2, MoS2, TaS, WS, SnSe, ReS, β-SnTe, MnO, AsS, P(black), InSe, h-BN, GaSe, GaN, SrTiO, MXene, and Janus 2D materials, which may form a two-dimensional material.

When viewed in a plan view, the word lines 79 may intersect the bit lines 50. For example, the word lines 79 may extend along side surfaces of the mold structures MS in the X-direction, and may be spaced apart from each other in the Y-direction. The word line 79 may be disposed on the channel structure 73. For example, the word line 79 may overlap the horizontal portion 73L of the channel structure 73 in a vertical direction. An upper end of the word line 79 may be located on a lower level than that of an upper surface of the mold structure MS.

The upper structure US may further include dielectric structures 76 between the word lines 79 and the channel structure 73. The dielectric structures 76 may be disposed between the word line 79 and the vertical channel portion 73S, and between the word line 79 and the horizontal portion 73L. In an example embodiment, a portion of the dielectric structure 76 may cover the upper surface of the upper mold layer M2, but the present disclosure is not limited thereto.

In one example, each of the dielectric structures 76 may be a tunnel dielectric layer that does not include an information storage layer. For example, each of the dielectric structures 76 may include at least one of silicon oxide and high-K dielectric. The high-K dielectric may include a metal oxide or a metal oxide. For example, the high-K dielectric may be formed of HfO₂, HfSiO, HfSiON, HfTaO, HfTiO, HfZrO, ZrO₂, Al₂O₃, or combinations thereof, but the present disclosure not limited thereto. Each of the dielectric structures 76 may be formed of a single layer or multiple layers of the materials described above.

In another example, each of the dielectric structures 76 may include an information storage layer and a dielectric layer. For example, each of the dielectric structures 76 may have polarization properties depending on the electrical field and may include a ferroelectric layer that may have remnant polarization by a dipole even without an external electrical field. Data may be recorded using such a polarization state in the ferroelectric layer. Accordingly, each of the dielectric structures 76 may include a ferroelectric layer that may be referred to as an information storage layer. The ferroelectric layer that may be the information storage layer may include an Hf-based compound, a Zr-based compound, and/or an Hf—Zr-based compound. For example, the Hf-based compound may be an HfO-based ferroelectric material, the Zr-based compound may include a ZrO-based ferroelectric material, and the Hf—Zr-based compound may include a hafnium zirconium oxide (HZO)-based ferroelectric material. The ferroelectric layer that may be the information storage layer may include impurities, for example, a ferroelectric material doped with at least one of C, Si, Mg, Al, Y, N, Ge, Sn, Gd, La, Sc, and Sr. For example, the ferroelectric layer that may be the information storage layer may be a material in which at least one of HfO₂, ZrO₂ and HZrO is doped with impurities, that is, at least one of C, Si, Mg, Al, Y, N, Ge, Sn, Gd, La, Sc and Sr. In the dielectric structures 76, the information storage layer is not limited to the aforementioned material type, and may include a material capable of storing information.

An upper insulating structure 81 may be disposed between the mold structures MS and may cover the word lines 79. The upper insulating structures 81 may extend in the X-direction and may be spaced apart from each other in the Y-direction. The upper insulating structures 81 may be alternately disposed with the mold structures MS in the Y-direction. The upper insulation structure 81 may include a first upper insulation layer 81a and a second upper insulation layer 81b. The first upper insulating layer 81a may be conformally disposed along surfaces of the bit line 50, the channel structure 73, the dielectric structure 76, and the word line 79. The second upper insulating layer 81b may be disposed on the first upper insulating layer 81a and may fill a space between the mold structures MS. In an example embodiment, a portion of the first upper insulating layer 81a may cover a portion of a dielectric structure covering an upper surface of the upper mold layer M2. The first upper insulating layer 81a and the second upper insulating layer 81b may include silicon oxide, silicon nitride, silicon oxynitride, a low dielectric, or combinations thereof. For example, the first upper insulating layer 81a may include silicon nitride, and the second upper insulating layer 81b may include silicon oxide.

The upper capping layer 82 may cover the mold structure MS and the upper insulating structure 81 and may extend in a horizontal direction. The upper capping layer 82 may be in contact with an upper surface of the first upper insulating layer 81a and an upper surface of the second upper insulating layer 81b. The upper capping layer 82 may include silicon nitride.

The landing pad structure 83 may be disposed on the channel structure 73 and may penetrate through the upper capping layer 82 to come into contact with the vertical channel portion 73S of the channel structure 73. The landing pad structure 83 may be electrically connected to the bit line 50 through the channel structure 73.

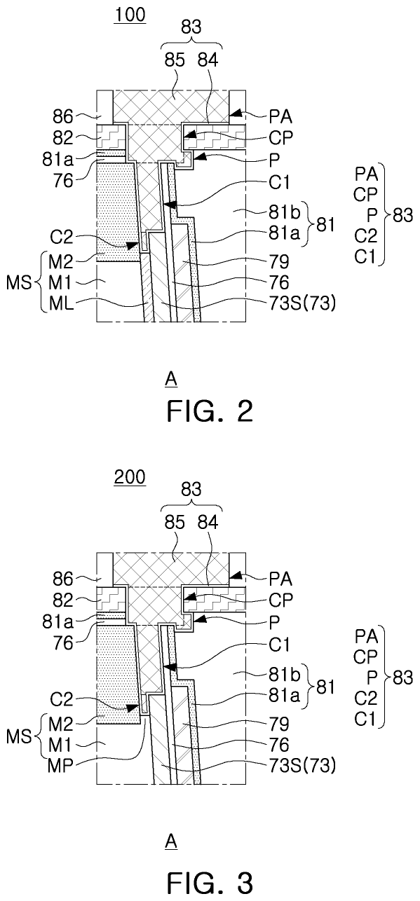

FIG. 2 is a partially enlarged view of the semiconductor device illustrated in FIG. 1B. Referring further to FIG. 2, a landing pad structure 83 may be comprised of a metal layer 85 and a barrier layer 84 covering a side surface and a bottom surface of the metal layer 85. The barrier layer 84 may include at least one of TiN, TaN, WN, TiSiN, TaSiN, TaSiN, and RuTiN, and the metal layer 85 may include a metal material such as W or Mo.

In an example embodiment, the landing pad structure 83 may include a first contact portion C1, a second contact portion C2, a protrusion P, a connection portion CP, and a pad portion PA. The pad portion PA may refer to a portion of the landing pad structure 83 disposed on an upper capping layer 82, and may be in contact with a first electrode 88a of an information storage structure 87 described below. The connection portion CP may be disposed below the pad portion PA and may vertically penetrate through the upper capping layer 82. For example, the connection portion CP may refer to a portion of the landing pad structure 83 disposed between a lower surface of the pad portion PA and an upper surface of the mold structure MS. The first contact portion C1 may be disposed below the connection portion CP and may be in contact with an upper surface of the channel structure 73. For example, the first contact portion C1 may refer to a portion of the landing pad structure 83 disposed between the upper surface of the mold structure MS and an upper surface of a vertical channel portion 73S. A horizontal width of the first contact portion C1 in the Y-direction may be greater than a horizontal width of the channel structure 73 in the Y-direction.

The second contact portion C2 may be in contact with the channel structure 73 and the liner ML. For example, the second contact portion C2 may refer to a portion of the landing pad structure 83 between the upper surface of the vertical channel portion 73S and the upper surface of the liner ML. The second contact portion C2 may have a shape protruding downwardly from a lower surface of the first contact portion C1. In an example embodiment, the second contact portion C2 may be in contact with a side surface of the vertical channel portion 73S, an upper surface of the liner ML, and a side surface of the upper mold layer M2. In an example embodiment, a lower surface of the second contact portion C2 may be disposed on a higher level than an upper surface of the lower mold layer M1, but the present disclosure is not limited thereto. The second contact portion C2 may overlap the first contact portion C1 in a vertical direction. An upper region of the vertical channel portion 73S may be disposed between the second contact portion C2 and a word line 79. For example, a horizontal distance between the second contact portion C2 and an adjacent word line 79 may be smaller than a horizontal distance between the first contact portion C1 and an adjacent word line 79. A horizontal width of the second contact portion C2 in the Y-direction may be identical to a horizontal width of the liner ML in the Y-direction.

As illustrated in FIG. 2, the landing pad structure 83 according to example embodiments of the present disclosure may be in contact with an upper surface and a side surface of the vertical channel portion 73S of the channel structure 73, thus increasing a contact area between the landing pad structure 83 and the channel structure 73. Accordingly, contact resistance between the landing pad structure 83 and the channel structure 73 may be reduced, and electrical characteristics of the semiconductor device 100 may be improved.

The protrusion P may be in contact with an upper insulating structure 81. For example, the protrusion P may refer to a portion of the landing pad structure 83 protruding from a lower portion of the connection portion CP toward the upper insulation structure 81. An upper surface of the protrusion P may be disposed on a lower level than that an upper surface of the connection portion CP, and a lower surface of the protrusion P may be disposed on a lower level than that of a lower surface of the connection portion CP. The protrusion P may be in contact with a lower surface of the upper capping layer 82 and a side surface of a second upper insulating layer 81b.

An upper structure US may further include insulation patterns 86 disposed on the upper capping layer 82 and disposed between the landing pad structures 83. The insulating pattern 86 may cover a side surface of the pad portion PA of the landing pad structure 83 and may electrically insulate the landing pad structures 83 from each other. The insulating pattern 86 may include silicon oxide, silicon nitride, silicon oxynitride, a low dielectric material, or combinations thereof. For example, the insulating pattern 86 may include silicon oxide.

Referring back to FIG. 1B, the information storage structure 87 may be disposed on the upper structure US. The information storage structure 87 may include first electrodes 88a electrically connected to and in contact with the landing pad structures 83, a second electrode 88c on the first electrodes 88a, and a dielectric layer 88b between the first electrodes 88a and the second electrode 88c.

In an example, the information storage structure 87 may be a capacitor configured to store information in a DRAM. For example, the dielectric layer 88b of the information storage structure 87 may be a capacitor dielectric layer of the DRAM, and the dielectric layer 87b may include a high-K dielectric material, silicon oxide, silicon nitride, silicon oxynitride, or combinations thereof.

In another example, the information storage structure 87 may be a structure configured to store information of a memory different from that of the DRAM. For example, the information storage structure 87 may be a capacitor of a ferroelectric memory (FeRAM). For example, the dielectric layer 88b may be a ferroelectric layer configured to record data using a polarization state. In another example, the dielectric layer 88b may include a lower dielectric layer and a ferroelectric layer on the lower dielectric layer. Here, the lower dielectric layer may include at least one of silicon oxide, silicon oxynitride, silicon nitride, and a high-K dielectric. In an example embodiment, when the dielectric structures 76 include an information storage layer, the information storage structure 87 may be omitted.

FIGS. 3 to 7 are vertical cross-sectional views of a semiconductor device according to an example embodiment. Referring to FIG. 3, a landing pad structure 83 of a semiconductor device 200 may include a first contact portion C1 and a second contact portion C2 disposed on a side surface of a mold structure MS and in contact with a vertical channel portion 73S of a channel structure 73. In an example embodiment, the liner ML illustrated in FIG. 2 may include the same material as the lower mold layer M1 and may be integrally formed. The lower mold layer M1 may include a protrusion MP protruding upwardly. An upper surface of the protrusion MP may be disposed on a level higher than that of a lower surface of an upper mold layer M2. The protrusion MP may be in contact with a side surface of the upper mold layer M2, a side surface of the vertical channel portion 73S, and a lower surface of the second contact portion C2.

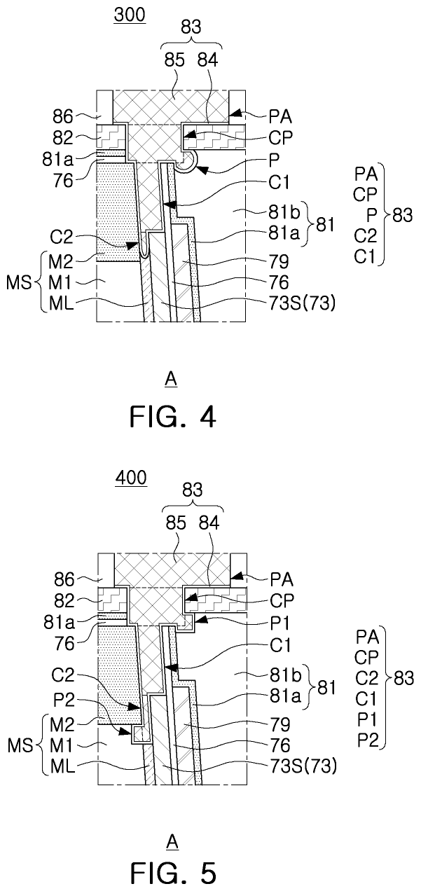

Referring to FIG. 4, a landing pad structure 83 of a semiconductor device 300 may include a first contact portion C1 and a second contact portion C2 in contact with a vertical channel portion 73S of a channel structure 73. In an example embodiment, a lower surface of the second contact portion C2 may be rounded and convex downwardly. A lower end of the second contact portion C2 may be disposed on a level higher than that of an upper surface of a lower mold layer M1. In an example embodiment, a side surface of a protrusion P of a landing pad structure 83 may be rounded.

Referring to FIG. 5, a landing pad structure 83 of a semiconductor device 400 may include a first contact portion C1 and a second contact portion C2 in contact with a vertical channel portion 73S of a channel structure 73. In an example embodiment, the second contact portion C2 may include a protrusion P2 protruding from a side surface of the second contact portion C2 toward a lower mold layer M1 (e.g., in a direction away from an adjacent word line 79). For example, the protrusion P2 may be in contact with the lower mold layer M1, a lower surface of an upper mold layer M2, an upper surface of a liner ML, and a side surface of the vertical channel portion 73S.

The protrusion P2 may have a structure identical or similar to the protrusion P described with reference to FIG. 2. For example, the protrusion P2 may protrude from a lower portion of a connection portion CP toward an upper insulating structure 81.

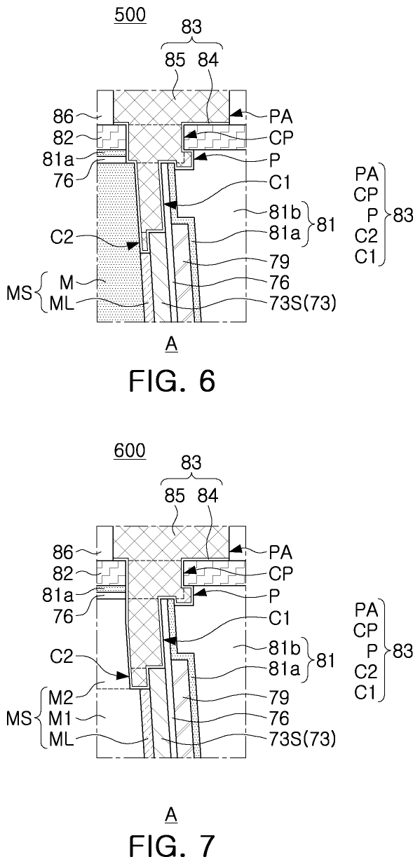

Referring to FIG. 6, a landing pad structure 83 of a semiconductor device 500 may include a first contact portion C1 and a second contact portion C2 in contact with a vertical channel portion 73S of a channel structure 73. In an example embodiment, the upper mold layer M2 and the lower mold layer M1 illustrated in FIGS. 1B and 2 may include the same material and may be integrally formed. For example, a mold structure MS may include a mold layer M and a liner ML disposed on a side surface of the mold layer M. In an example embodiment, the mold layer M may include silicon nitride or silicon oxide.

Referring to FIG. 7, a landing pad structure 83 of a semiconductor device 600 may include a first contact portion C1 and a second contact portion C2 in contact with a vertical channel portion 73S of a channel structure 73. In an example embodiment, the upper mold layer M2 and the lower mold layer M1 illustrated in FIGS. 1B and 2 may include the same material and may be integrally formed. Unlike the example embodiment illustrated in FIG. 6, a step portion may exist between the lower mold layer M1 and the upper mold layer M2. For example, the lower mold layer M1 may have a greater horizontal width than that of the upper mold layer M2, and the lower mold layer M1 may have a shape protruding horizontally from a side surface of the upper mold layer M2. In an example embodiment, the lower mold layer M1 and the upper mold layer M2 may include the same material as a liner ML. For example, the lower mold layer M1, the upper mold layer M2, and the liner ML may include silicon oxide.

In an example embodiment, a horizontal width of the first contact portion C1 in the Y-direction may be greater than the sum of horizontal widths of the vertical channel portion 73S and the liner ML in the Y-direction. A horizontal width of the second contact portion C2 in the Y-direction may be greater than the horizontal width of the liner ML in the Y-direction.

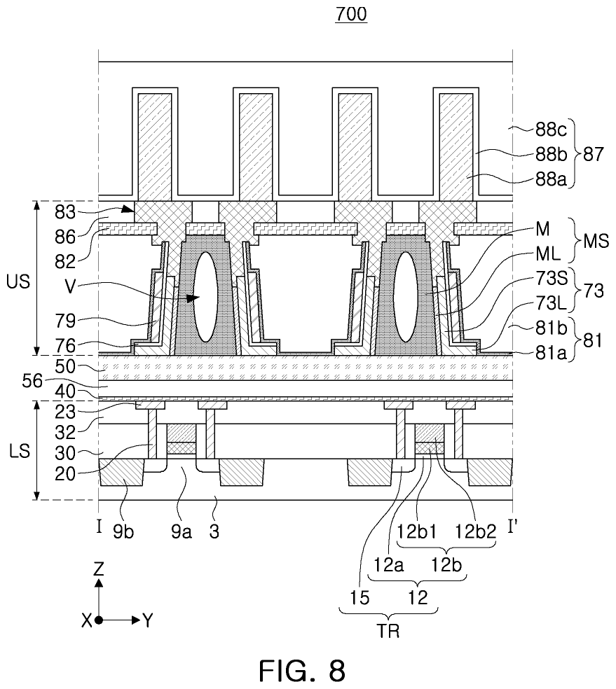

Referring to FIG. 8, a semiconductor device 700 may include a mold structure MS including a void V therein. In an example embodiment, the upper mold layer M2 and the lower mold layer M1 illustrated in FIGS. 1B and 2 may include the same material and may be integrally formed, thus forming a mold layer M. The mold layer M may include the void V therein, and a liner ML may be disposed on a side surface of the mold layer M. The void may reduce coupling noise between word lines 79 adjacent to each other.

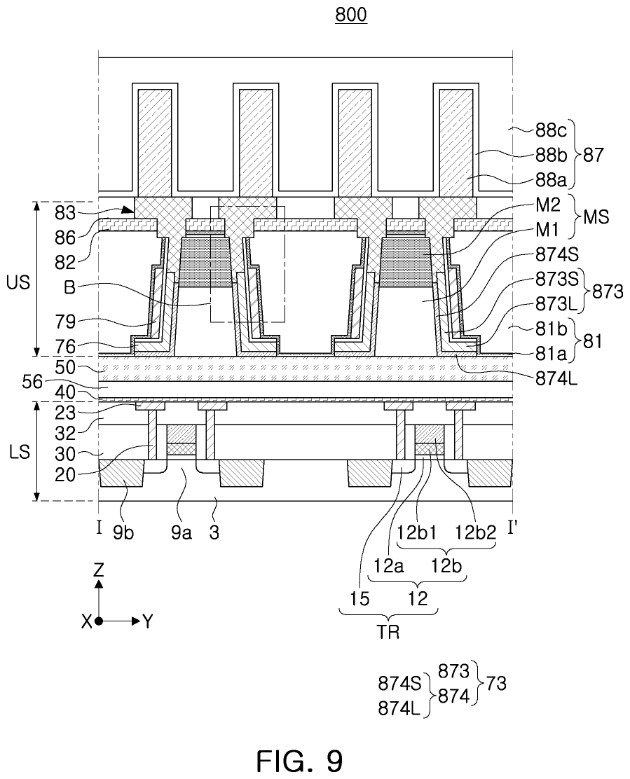

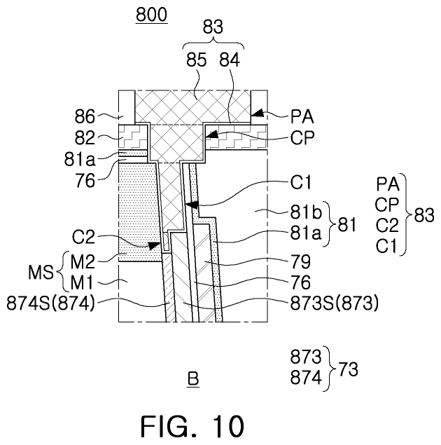

FIG. 9 is a vertical cross-sectional view of a semiconductor device according to an example embodiment; and FIG. 10 is a partially enlarged view of the semiconductor device illustrated in FIG. 9. Referring to FIGS. 9 and 10, a landing pad structure 83 of a semiconductor device 800 may include a first contact portion C1 and a second contact portion C2 in contact with a vertical channel portion 73S of a channel structure 73. In an example embodiment, the channel structure 73 may be formed of a plurality of layers. For example, the channel structure 73 may include an internal channel structure 874 and an external channel structure 873 disposed on the internal channel structure 874. The internal channel structure 874 may include an internal horizontal portion 874L in contact with and electrically connected to a bit line 50 and an internal vertical channel portion 874S extending upwardly from one end of the internal horizontal portion 874L in the Y-direction. The external channel structure 873 may include an external horizontal portion 873L in contact with the internal horizontal portion 8743L and an external vertical channel portion 873S in contact with the internal vertical channel portion 874S.

In an example embodiment, the internal channel structure 874 may include the same material as the external channel structure 873. In an example embodiment, an upper surface of the internal channel structure 874 may be disposed on a lower level than that of an upper surface of the external channel structure 873. For example, an upper surface of the internal vertical channel portion 874S may be disposed on a lower level than that of the upper surface of the external vertical channel portion 873S. The first contact portion C1 may be in contact with the upper surface of the external vertical channel portion 873S, and the second contact portion C2 may be in contact with a side surface of the external vertical channel portion 873S and the upper surface of the internal vertical channel portion 874S. FIGS. 9 and 10 illustrate that thicknesses of the internal channel structure 874 and the external channel structure 873 are different from each other, but the present disclosure is not limited thereto. In some example embodiments, the thicknesses of the internal channel structure 874 and the external channel structure 873 may be the same.

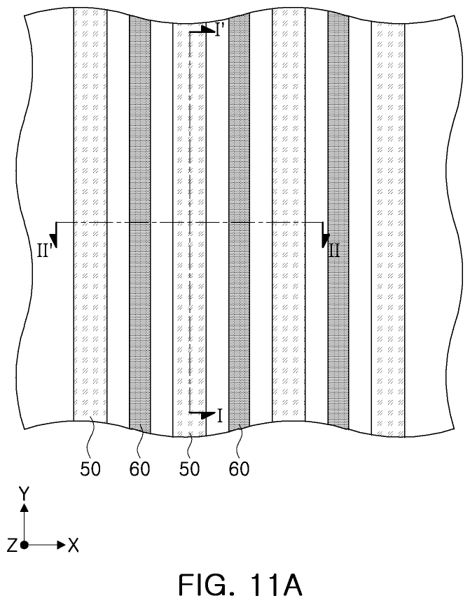

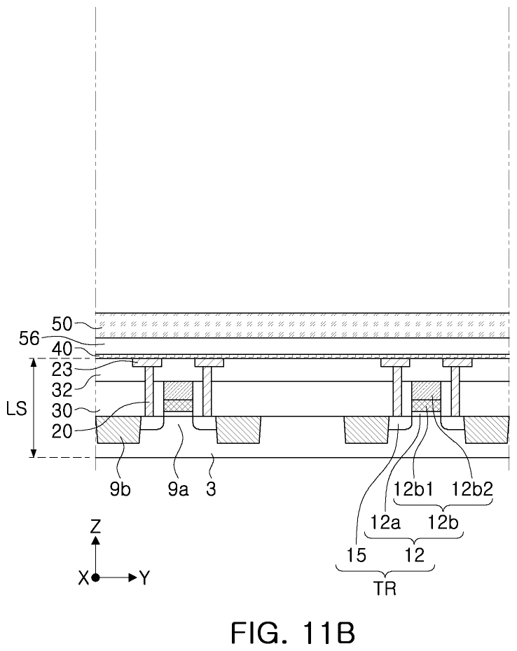

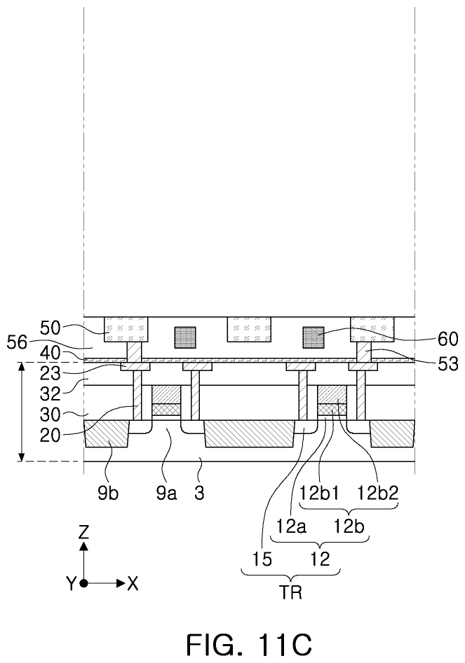

FIGS. 11A to 21 are plan views and vertical cross-sectional views illustrated in accordance with a process order to explain a method of manufacturing a semiconductor device according to an example embodiment. In particular, FIGS. 11A, 12A, 13A, 14A, 15A, 16A, and 17A are plan views corresponding to FIG. 1. FIGS. 11B, 12B, 13B, 14B, 15B, 16B, 17B, 18, 19, 20, and 21 are vertical cross-sectional views corresponding to FIG. 1B. FIGS. 11C, 13C, 14C, 15C, and 17C are vertical cross-sectional views corresponding to FIG. 1C.

Referring to FIGS. 11A to 11C, a lower structure LS may be formed. The lower structure LS may include the substrate 3, the circuit element TR on the substrate 3, the peripheral wiring 23 and the peripheral plug 20 electrically connected to the circuit element TR, the first peripheral insulating layer 30 surrounding a side surface of the peripheral plug 20 and a side surface of the circuit element TR, and a second peripheral insulating layer 32 surrounding the peripheral wiring 23 and the peripheral plug 20.

An etching stop layer 40 may be formed on the lower structure LS. The etching stop layer 40 may cover the peripheral wiring 23 and the second peripheral insulating layer 32. A bit line 50, a bit line plug 53, a bit line insulating layer 56, and a shield pattern 60 may be formed on the etching stop layer 40. For example, the bit line plug 53 may be formed to penetrate through the etching stop layer 40 and in contact with the peripheral wiring 23, and the bit line 50 may be formed on the bit line plug 53. An insulating material may be deposited to cover the bit line plug 53 and the bit line 50, and the shield pattern 60 may be formed on the insulating material. Then, an insulating material may be further deposited to cover the shield pattern 60, thus forming the bit line insulating layer 56. The bit lines 50 may extend in the Y-direction and may be spaced apart from each other in the X-direction. The shield patterns 60 may extend in the Y-direction and may be spaced apart from each other in the X-direction. The shield patterns 60 may be alternately disposed with the bit lines 50 in the X-direction.

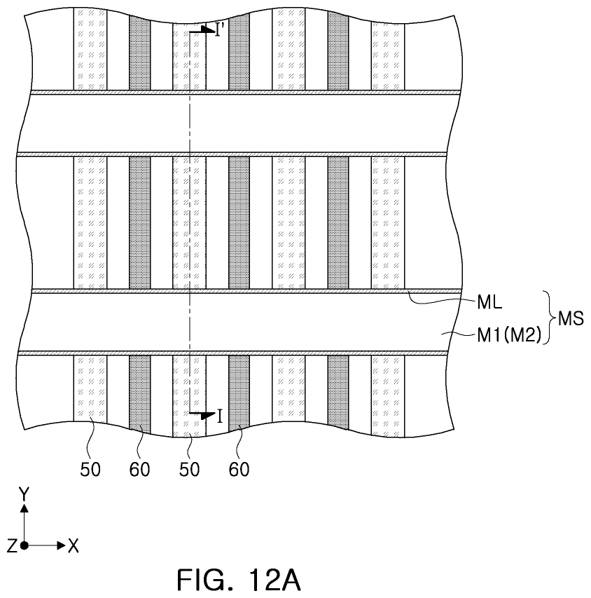

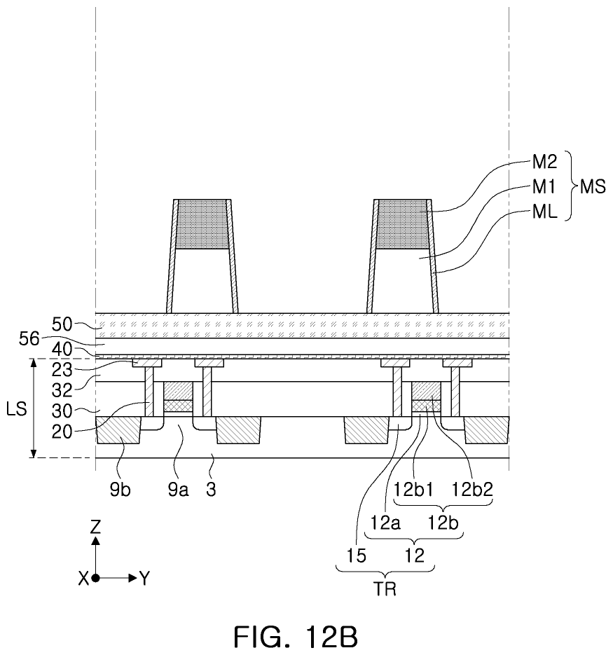

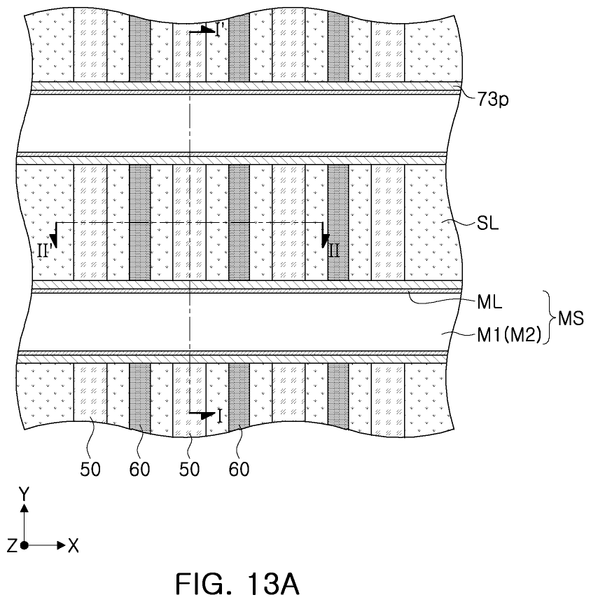

Referring to FIGS. 12A and 12B, a mold structure MS may be formed on the bit line 50 and a bit line insulating layer 56. A lower insulating material and an upper insulating material may be sequentially stacked to cover the bit line 50 and the bit line insulating layer 56, and then the lower insulating material and the upper insulating material may be patterned to form a lower mold layer M1 and an upper mold layer M2. Then, an insulating material may be formed to cover the bit line 50, the bit line insulating layer 56, the lower mold layer M1, and the upper mold layer M2, and then the insulating material may be anisotropically etched to form a liner ML. The lower mold layer M1, the upper mold layer M2, and the liner ML may form the mold structure MS. The lower mold layer M1 and the upper mold layer M2 may include silicon oxide, silicon nitride, silicon oxynitride, or combinations thereof. The liner ML may include silicon oxide, silicon oxynitride, hafnium oxide, or combinations thereof.

The mold structures MS may extend in the X-direction and may be spaced apart from each other in the Y-direction. The liner ML may cover side surfaces of the lower mold layer M1 and the upper mold layer M2. In an example embodiment, the mold structure MS may have a tapered shape in which a horizontal width thereof in the Y-direction decreases as it moves up, but the present disclosure is not limited thereto.

In an example embodiment, the lower mold layer M1 and the upper mold layer M2 may include different materials. For example, the lower mold layer M1 may include silicon oxide, and the upper mold layer M2 may include silicon nitride. In some example embodiments, the lower mold layer M1 and the upper mold layer M2 may include the same material and may be integrally formed.

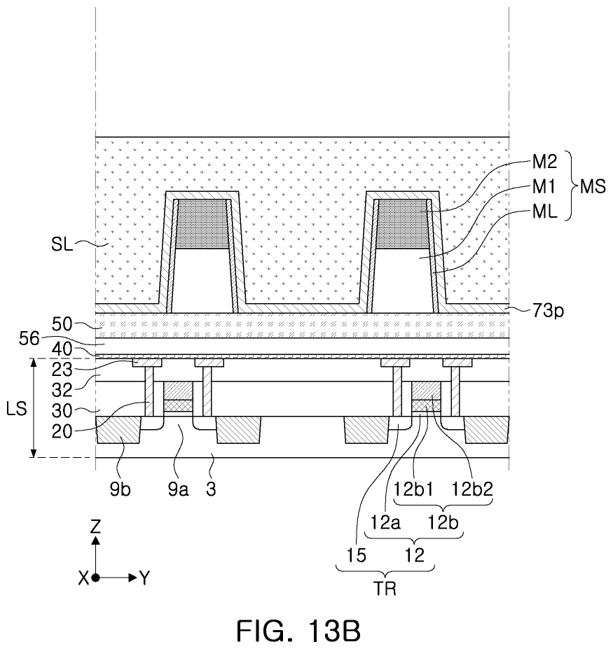

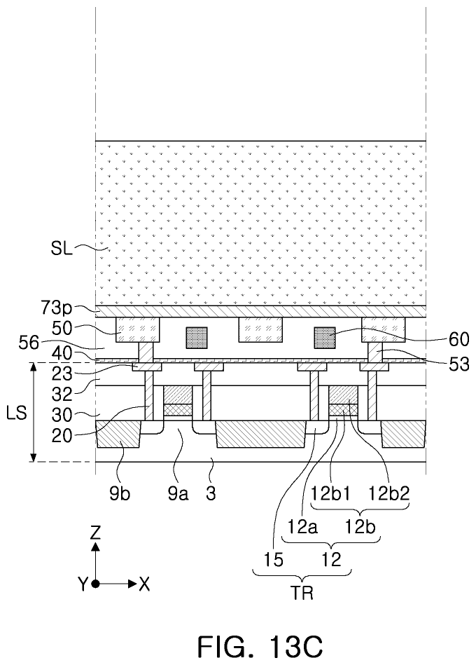

Referring to FIGS. 13A and 13B, a channel material layer 73p and a sacrificial layer SL may be formed. The channel material layer 73p may be formed to cover a bit line 50, a bit line insulating layer 56, and a mold structure MS. For example, the channel material layer 73p may conformally cover the mold structure MS. The sacrificial layer SL may be formed to cover the channel material layer 73p.

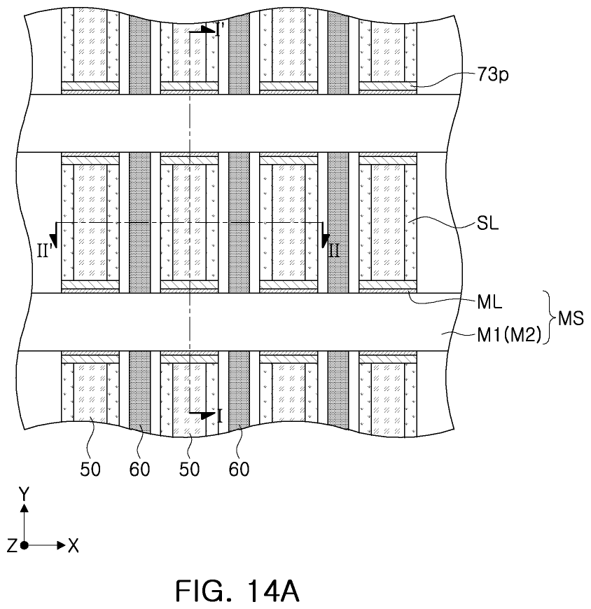

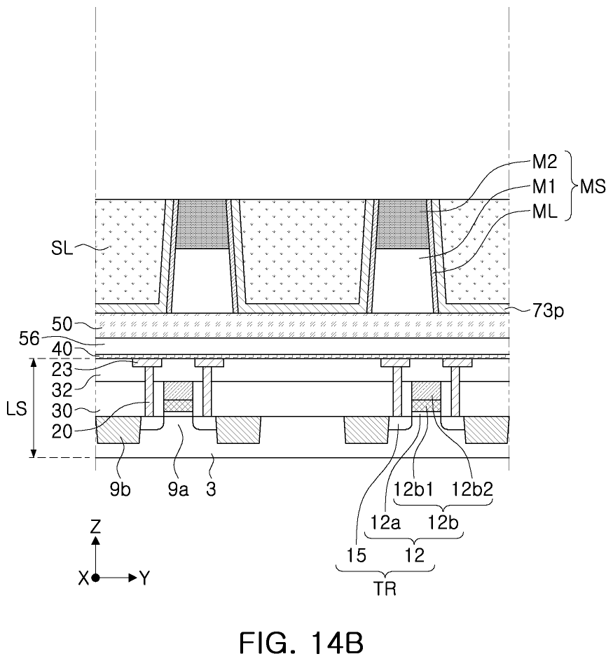

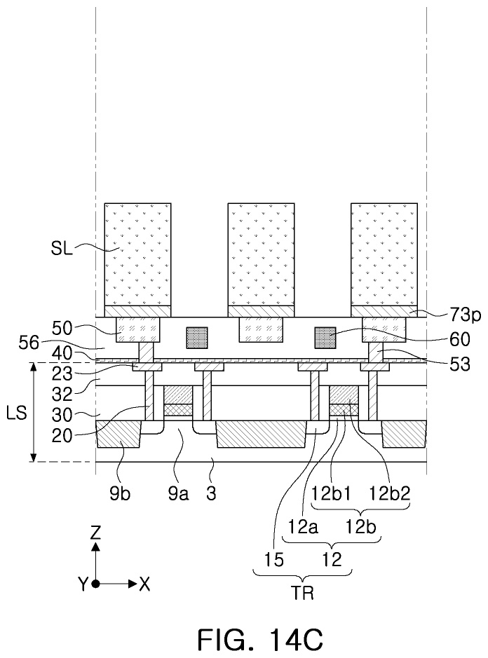

Referring to FIGS. 14A to 14C, a liner ML, a channel material layer 73p, and a sacrificial layer SL may be planarized and patterned. The channel material layer 73p and the sacrificial layer SL may be planarized so that an upper surface of a mold structure MS is exposed, and an upper surface of the channel material layer 73p and an upper surface of the sacrificial layer SL may be coplanar with the upper surface of the mold structure MS.

Furthermore, the channel material layer 73p and the sacrificial layer SL may be patterned by an anisotropic etching process, and an upper surface of a bit line insulating layer 56 may be partially exposed. In a plan view, the liners ML may be disposed on a side surface of a lower mold layer M1 and may be spaced apart from each other in the X-direction and in the Y-direction. The channel material layers 73p may be spaced apart from each other in the X-direction and the Y-direction while being in contact with the side surfaces of the liners ML.

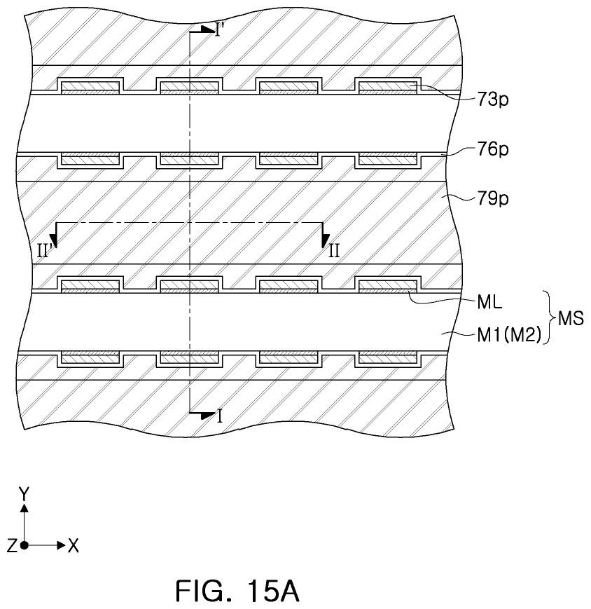

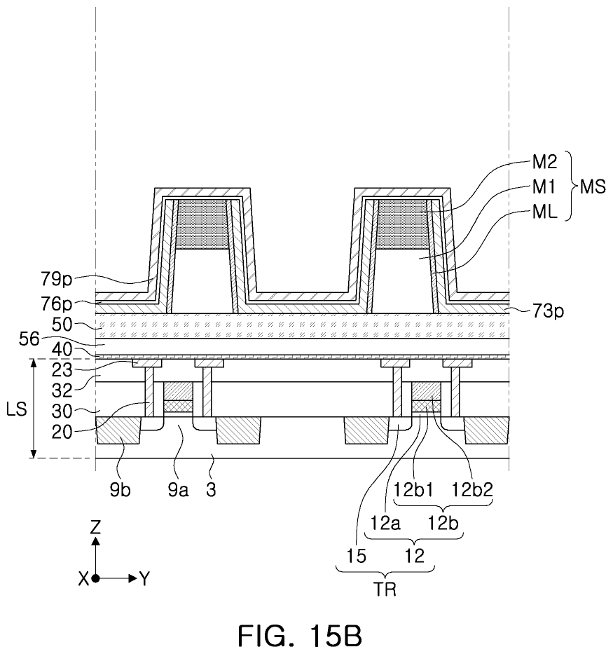

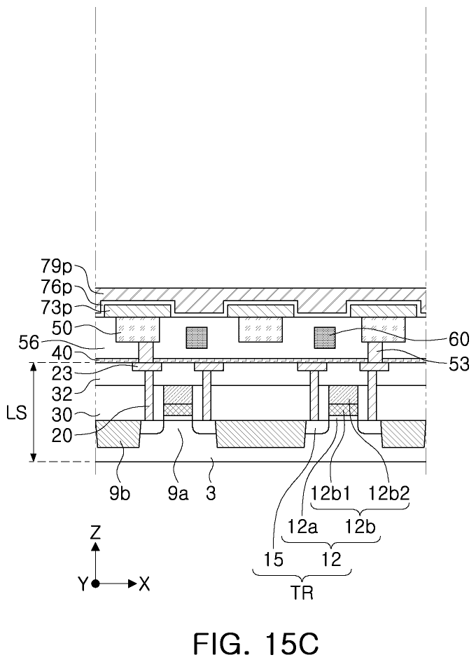

Referring to FIGS. 15A and 15B, a sacrificial layer SL may be removed, and a dielectric material layer 76p and a conductive layer 79p may be formed. The dielectric material layer 76p may be conformally formed along a bit line insulating layer 56, a channel material layer 73p, and a mold structure MS. The conductive layer 79p may cover the dielectric material layer 76p.

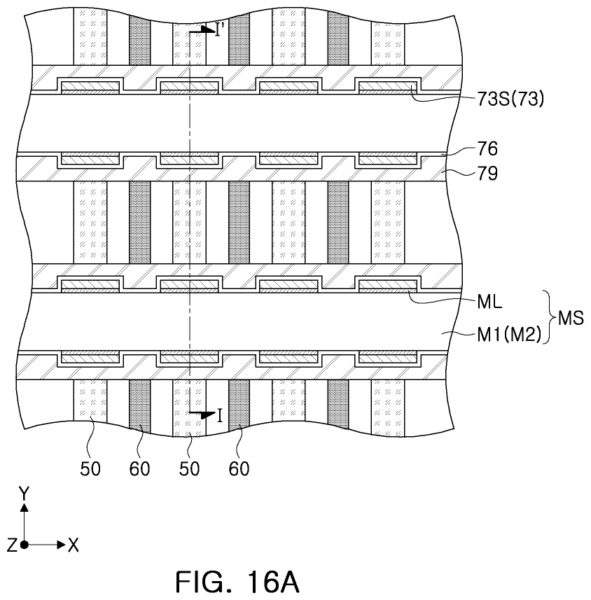

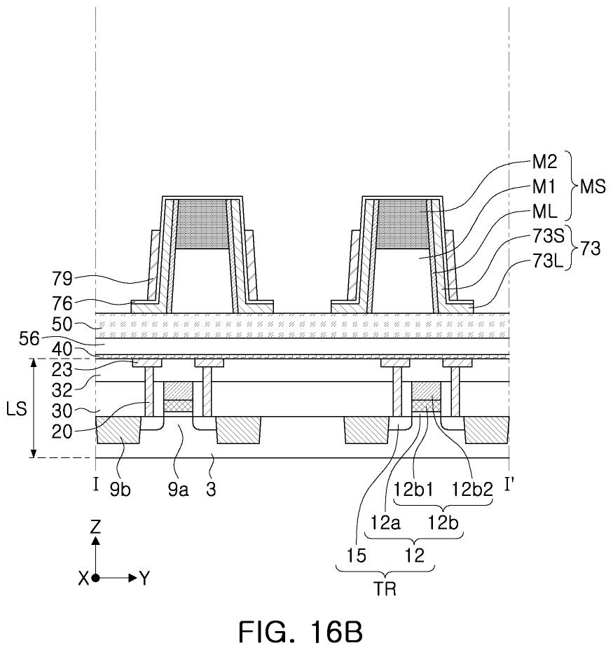

Referring to FIGS. 16A and 16B, a dielectric material layer 76p and a conductive layer 79p may be etched by an anisotropic etching process, thus forming a dielectric structure 76 and word lines 79. In an example embodiment, a portion of the dielectric structure 76 covering an upper surface of a mold structure MS may remain unremoved, but the present disclosure is not limited thereto. In some example embodiments, a portion of the dielectric structure 76 covering the upper surface of the mold structure MS may be removed, and the upper surface of the mold structure MS may be exposed.

In a plan view, word lines 79 may intersect bit lines 50. For example, the word lines 79 may be disposed on a side of the mold structure MS to extend in the X-direction, and may be spaced apart from each other in the Y-direction.

In an example embodiment, a portion of the channel material layer 73p may be etched between the mold structures MS to form a channel structure 73. The channel structure 73 may include a horizontal portion 73L in contact with the bit line 50 and to extend horizontally and a vertical channel portion 73S extending upwardly along a side surface of a liner ML. In an example embodiment, the vertical channel portion 73S may extend in a direction other than a vertical direction (Z-direction), but the present disclosure is not limited thereto. In some example embodiments, the vertical channel portion 73S may extend in the vertical direction. A portion of the channel material layer 73p may be etched to partially expose an upper surface of the bit line 50 between the mold structures MS. In some example embodiments, the channel material layer 73p may extend, without being broken, between adjacent mold structures MS in the Y-direction. For example, the channel material layer 73p may cover side surfaces of a plurality of mold structures MS, and the upper surface of the bit line 50 may not be exposed in FIG. 16b.

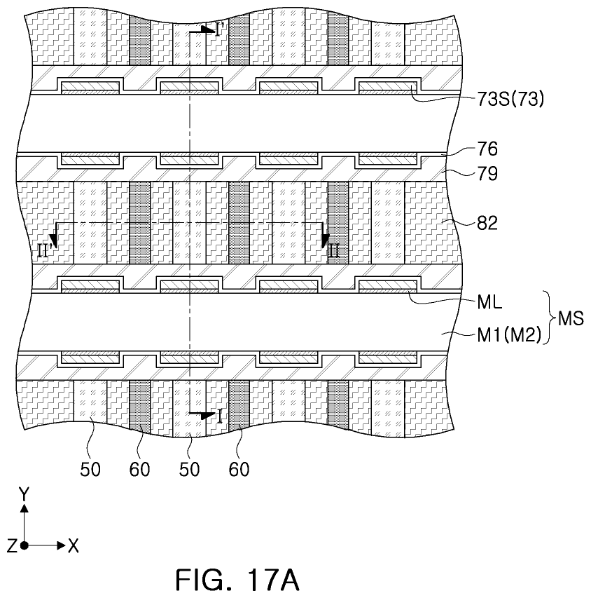

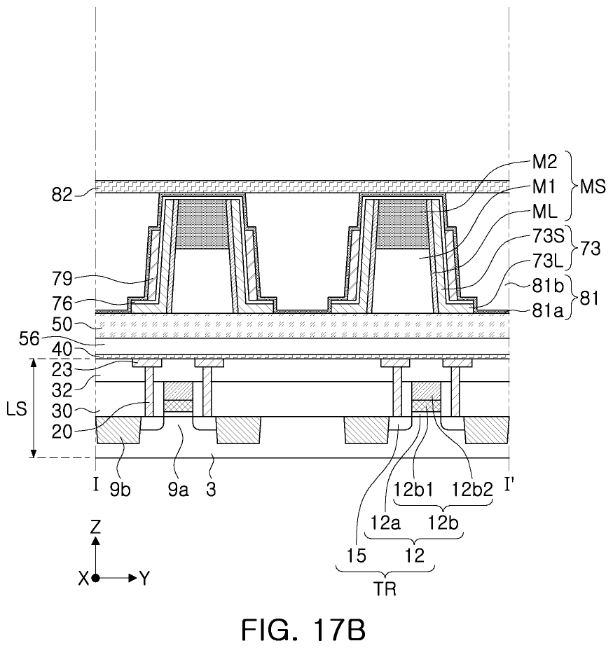

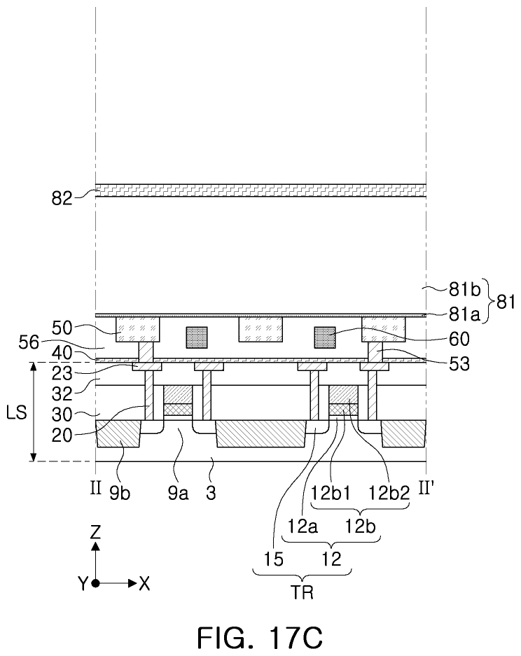

Referring to FIGS. 17A to 17C, an upper insulating structure 81 and an upper capping layer 82 may be formed. The upper insulation structure 81 may include a first upper insulation layer 81a and a second upper insulation layer 81b. The first upper insulating layer 81a may be conformally formed along a bit line 50, a bit line insulating layer 56, a channel structure 73, a dielectric structure 76, and a word line 79. The second upper insulating layer 81b may be formed by depositing an insulating material to cover the first upper insulating layer 81a and then planarizing the insulating material to expose an upper surface of the first upper insulating layer 81a. The upper insulating structures 81 may extend in the X-direction and may be spaced apart from each other in the Y-direction. The upper insulating structures 81 may be alternately disposed with the mold structures MS in the Y-direction. The upper capping layer 82 may cover an upper surface of the upper insulating structure 81.

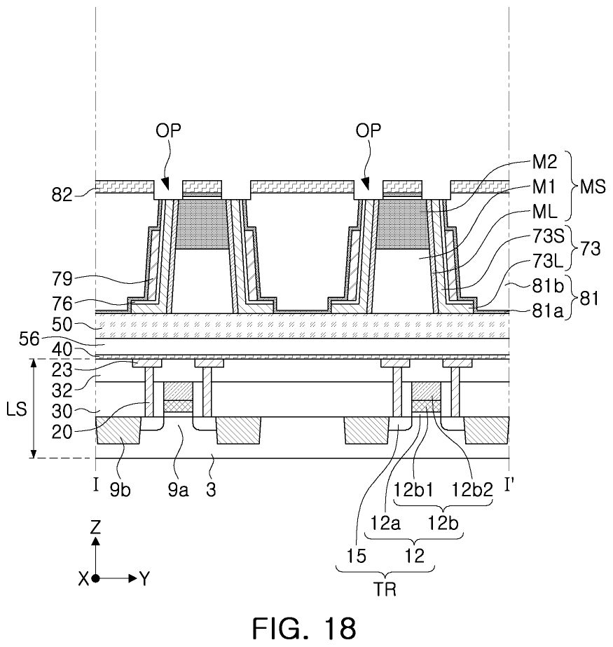

Referring to FIG. 18, an upper capping layer 82 may be etched by an anisotropic etching process, and an opening OP exposing a channel structure 73 may be formed.

The opening OP may expose an upper surface of the vertical channel portion 73S. The opening OP may also expose an upper mold layer M2, a liner ML, a dielectric structure 76 and an upper insulating structure 81.

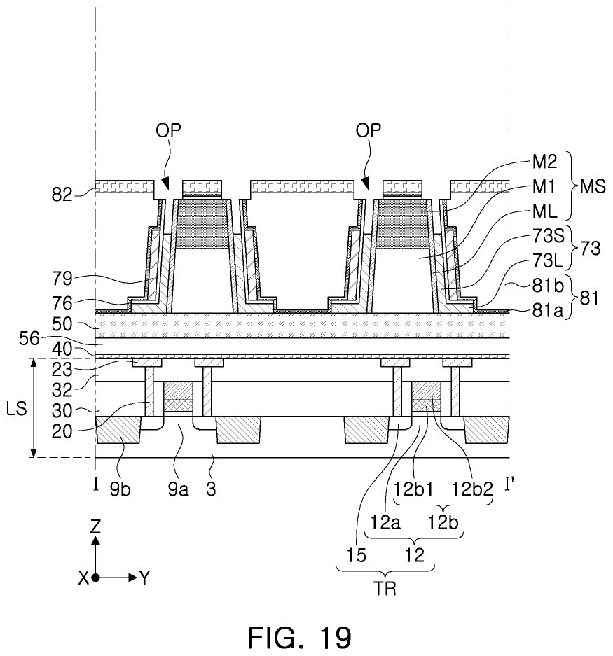

Referring to FIG. 19, a channel structure 73 may be selectively etched. Etching the channel structure 73 may include performing a first wet etching process. An etchant may flow into the opening OP, and an upper portion of a vertical channel portion 73S of the channel structure 73 may be selectively etched by the etchant. In an example embodiment, an upper surface of the etched vertical channel portion 73S may be higher than an upper surface of the lower mold layer M1. Since the liner ML includes a material having a selectivity ratio with the channel structure 73, the liner ML may not be etched. Side surfaces of the liner ML and the dielectric structure 76 may be partially exposed by the first wet etching process.

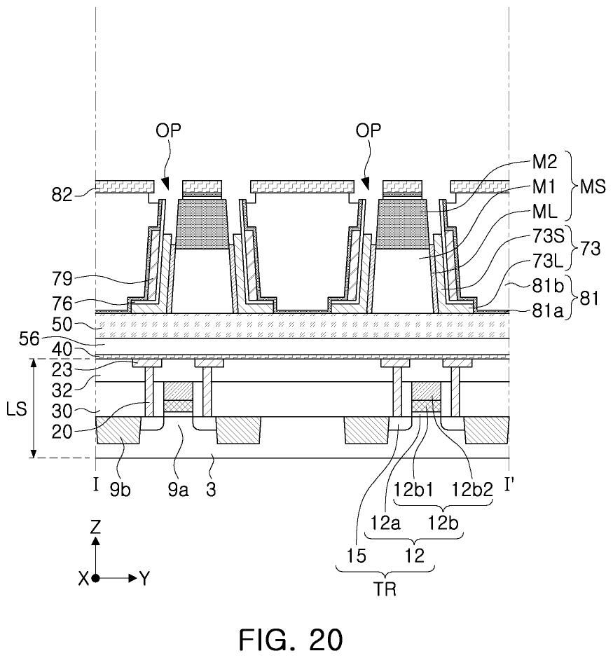

Referring to FIG. 20, a liner ML may be etched by a second wet etching process. Since the liner ML has an etching selectivity ratio with the channel structure 73, the channel structure 73 may not be etched, and the liner ML may be selectively etched. An upper surface of the etched liner ML may be disposed on a lower level than that of an upper surface of a vertical channel portion 73S. In an example embodiment, an upper surface of the liner ML may be disposed on a level higher than that of an upper surface of a lower mold layer M1, but the present disclosure is not limited thereto.

In an example embodiment, an upper insulating structure 81 may be partially etched by an etching process. For example, a second upper insulating layer 81b may include the same material as the liner ML, and a portion of the second upper insulating layer 81b may be etched together with the liner ML.

In an example embodiment, as illustrated in FIG. 4, the liner ML and the second upper insulating layer 81b may be etched to be rounded. In an example embodiment, as illustrated in FIG. 5, the liner ML may be etched so that the upper surface thereof is disposed on a lower level than that of the upper surface of the lower mold layer M1. Furthermore, when the lower mold layer M1 includes the same material as the liner ML, the lower mold layer M1 may be partially etched.

In an example embodiment, as illustrated in FIG. 7, when the lower mold layer M1 and the upper mold layer M2 contain the same material as the liner ML, the upper mold layer M2 may be partially etched.

In an example embodiment, as illustrated in FIG. 10, the liner ML may be replaced by the internal channel structure 73, and the channel structure 73 may include the internal channel structure 73 and the external channel structure 73. The internal channel structure 73 may include the same material as the external channel structure 73. However, the internal channel structure 73 may be formed by a physical vapor deposition (PVD) method, and the external channel structure 73 may be formed by an atomic layer deposition (ALD) method. The external channel structure 73 may be deposited more densely than the internal channel structure 73. When the second wet etching process is performed, an etching speed of the internal channel structure 73 formed by the PVD method may be different from an etching speed of the external channel structure 73 formed by the ALD method. Accordingly, the internal channel structure 73 may be etched faster, and the upper surface of the internal channel structure 73 may be disposed on a lower level than that of the upper surface of the external channel structure 73.

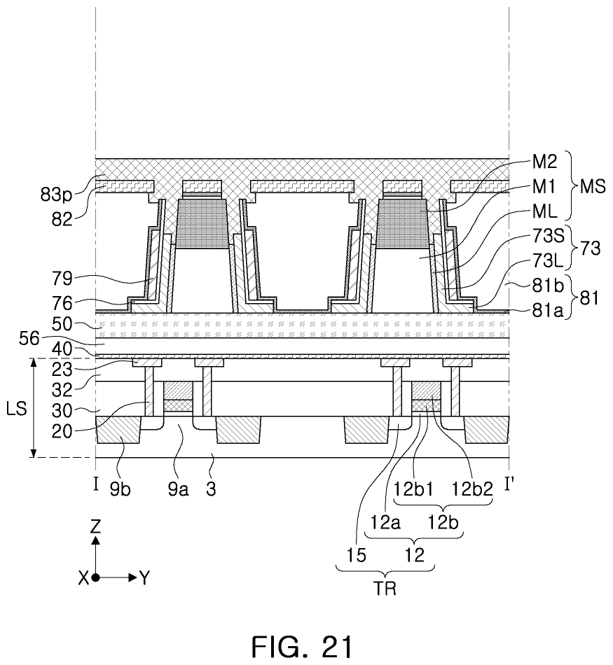

Referring to FIG. 21, a conductive layer 83p may be formed to cover an upper capping layer 82 while filling the opening. As illustrated in FIG. 2, the conductive layer 83p may include a barrier layer 84 and a metal layer 85. The conductive layer 83p may be in contact with an upper surface of a vertical channel portion 73S and an upper surface of a liner ML. The conductive layer 83p may also be in partial contact with a side surface of the vertical channel portion 73S. The conductive layer 83p may be electrically connected to a bit line 50 through a channel structure 73.

Referring back to FIGS. 1A to 1C, the conductive layer 83p may be patterned to form the landing pad structure 83. After depositing an insulating material to cover the landing pad structure 83, the insulating material may be planarized to expose an upper surface of the landing pad structure 83, thus forming an insulating pattern 86. The insulating pattern 86 may be disposed on the same level as that of the landing pad structures 83 and may electrically insulate the landing pad structures 83 from each other. The mold structure MS, the channel structure 73, the dielectric structure 76, the word line, the upper insulation structures 81, the upper capping layer 82, the landing pad structure 83, and the insulation patterns 86 may form an upper structure US.

An information storage structure 87 may be formed on the upper structure US to manufacture the semiconductor device 100. As described with reference to FIGS. 1A to 1C, the information storage structure 87 may include first electrodes 88a electrically connected to and in contact with the landing pads, the second electrode 88c on the first electrodes 88a, and the dielectric layer 88b between the first electrodes 88a and the second electrode 88c.

As illustrated in FIG. 20, the second contact portion C2 may be disposed in a space in which the liner ML is etched by a wet etching process. Since the second contact portion C2 is magnetically aligned and disposed, defects in the process may be prevented and reduced as compared to a case in which an exposure process is performed to form a space in which the second contact portion C2 is disposed.

Accordingly, the second contact portion C2 having a finer pattern than the first contact portion C1 may be formed, thereby preventing and reducing defects in the semiconductor device 100.

While the inventive concept has been particularly shown and described with reference to embodiments thereof, it will be understood that various changes in form and details may be made therein without departing from the spirit and scope of the following claims.

1. An integrated circuit memory device, comprising:
a substrate;
a bit line extending in a first horizontal direction on the substrate;
a channel structure extending on the bit line, the channel structure including a horizontal portion on the bit line and a vertical channel portion extending upwardly from one end of the horizontal portion;
a word line on the horizontal portion and crossing the bit line to extend in a second horizontal direction, intersecting the first horizontal direction; and
a landing pad structure electrically connected to the vertical channel portion, the landing pad structure including a first contact portion in contact with an upper surface of the vertical channel portion and a second contact portion protruding downwardly from a lower surface of the first contact portion.

2. The device of claim 1, wherein a horizontal width of the first contact portion is greater than a horizontal width of the vertical channel portion.

3. The device of claim 1, wherein the second contact portion is in contact with a side surface of the vertical channel portion.

4. The device of claim 1, wherein an upper region of the vertical channel portion extends between the second contact portion and the word line.

5. The device of claim 1, further comprising:
an electrically insulating mold structure extending on the bit line, in the second horizontal direction;
wherein the mold structure includes a lower mold layer, an upper mold layer on the lower mold layer, and a liner on a side surface of the lower mold layer; and
wherein the liner extends between the lower mold layer and the vertical channel portion.

6. The device of claim 5, wherein the second contact portion is in contact with an upper surface of the liner.

7. The device of claim 5, wherein the vertical channel portion is spaced apart from the lower mold layer.

8. The device of claim 5, wherein a lower surface of the second contact portion is disposed at a higher level than an upper surface of the lower mold layer, relative to an upper surface of the substrate.

9. The device of claim 5, wherein the liner includes at least one of silicon oxide, silicon oxynitride, and hafnium oxide.

10. The device of claim 5, wherein a lower surface of the second contact portion is convex downwardly.

11. The device of claim 5, wherein the lower mold layer includes the same material as the upper mold layer and is integrally formed.

12. The device of claim 5, wherein the lower mold layer and the upper mold layer include the same material as the liner; and wherein the lower mold layer has a shape protruding horizontally from a side surface of the upper mold layer.

13. The device of claim 5, wherein the mold structure has a void therein.

14. The device of claim 1, further comprising:
an upper insulating structure covering upper surfaces of the bit line and the word line; and
wherein the landing pad structure further includes a first protrusion protruding to the upper insulating structure.

15. The device of claim 1, wherein the landing pad structure further includes a second protrusion protruding from a side surface of the second contact portion in a direction away from the word line.

16. The device of claim 1,
wherein the channel structure includes an internal channel structure and an external channel structure extending on the internal channel structure;
wherein an upper surface of the external channel structure extends on a higher level than an upper surface of the internal channel structure;
wherein the first contact portion is in contact with the upper surface of the external channel structure; and
wherein the second contact portion is in contact with a side surface of the external channel structure and the upper surface of the internal channel structure.

17. An integrated circuit memory device, comprising:
a bit line extending in a first horizontal direction;
a mold structure extending on the bit line, and in a second horizontal direction intersecting the first horizontal direction, the mold structure including a mold layer and a liner on a side surface of the mold layer;
a channel structure extending on the bit line, the channel structure including a horizontal portion on the bit line and a vertical channel portion extending upwardly from one end of the horizontal portion, and extending on a side surface of the liner;
a word line extending on the horizontal portion and crossing the bit line to extend in the second horizontal direction; and
a landing pad structure on the vertical channel portion and electrically connected to the channel structure;
wherein an upper surface of the vertical channel portion extends on a higher level than an upper surface of the liner;
wherein the landing pad structure includes a first contact portion in contact with the upper surface of the vertical channel portion, and a second contact portion in contact with a side surface of an upper region of the vertical channel portion and the upper surface of the liner.

18. The device of claim 17, wherein the mold structure includes a lower mold layer and an upper mold layer on the lower mold layer; wherein the lower mold layer includes the same material as the liner and is integrally formed; and wherein a portion of the lower mold layer extends on a higher level than a lower surface of the upper mold layer.

19. The device of claim 17, wherein a horizontal width of the second contact portion is identical to a horizontal width of the liner.

20. A integrated circuit memory device, comprising:
a lower substructure including a circuit element;
a bit line disposed on the lower structure and extending in a first horizontal direction;
a mold structure disposed on the bit line, and extending in a second horizontal direction that intersects the first horizontal direction, the mold structure including a mold layer and a liner on a side surface of the mold layer;
a channel structure disposed on the bit line, wherein the channel structure includes a horizontal portion on the bit line and a vertical channel portion extending upwardly from one end of the horizontal portion and disposed on a side surface of the liner;
a word line disposed on the horizontal portion and crossing the bit line to extend in the second horizontal direction;
an upper insulating structure spaced apart from the mold structure in the second horizontal direction and configured to cover the word line and the bit line;
an upper capping layer configured to cover the mold structure and the upper insulating structure;
a landing pad structure disposed on the vertical channel portion, penetrating through the upper capping layer, and electrically connected to the channel structure; and
an information storage structure on the landing pad structure;
wherein the landing pad structure includes a pad portion on the upper capping layer, a first contact portion in contact with an upper surface of the vertical channel portion, a second contact portion in contact with a side surface of the vertical channel portion and an upper surface of the liner, and a connection portion between the pad portion and the first contact portion.

21.-30. (canceled)
